(19) United States
(12) Patent Application Publication
(10) Pub. No.: US 2020/0043829 A1
(43) Pub. Date: Feb. 6, 2020

(54) THERMAL MANAGEMENT SOLUTIONS FOR STACKED INTEGRATED CIRCUIT DEVICES

(71) Applicant: Intel Corporation, Santa Clara, CA (US)

(72) Inventors: Adel Elsherbini, Chander, AZ (US); Feras Eid, Chandler, AZ (US); Johanna Swan, Scottsdale, AZ (US)

(21) Appl. No.: 16/055,428

(22) Filed: Aug. 6, 2018

(51) Int. Cl. H01L 23/473; H01L 25/065; H01L 23/00; H01L 23/522

(52) U.S. Cl. CPC H01L 23/473; H01L 25/0657; H01L 23/5226; H01L 24/17; H01L 24/09; H01L 24/33

(57) ABSTRACT

An integrated circuit structure may be formed having a substrate, a first integrated circuit device electrically attached to the substrate, a second integrated circuit device electrically attached to the first integrated circuit device, at least one first level channel between the substrate and the first integrated circuit device and/or at least one second level channel between the first integrated circuit device and the second integrated circuit device, and a heat dissipation device attached to the substrate which defines a fluid chamber, wherein the at least one of the first level channel and/or the at least one second level channel is opened to the fluid chamber, such that when a heat transfer fluid is introduced into the fluid chamber, the heat transfer fluid may make direct contact with the first integrated circuit device and/or the second integrated circuit device.

### TECHNICAL FIELD

Embodiments of the present description generally relate to the removal of heat from integrated circuit devices, and, more particularly, to thermal management solutions wherein a heat transfer fluid of a heat dissipation device is in physical contact with stacked integrated circuit devices within an integrated circuit device package.

### BACKGROUND

Higher performance, lower cost, increased miniaturization, and greater packaging density of integrated circuits within integrated circuit devices are ongoing goals of the electronics industry. As these goals are achieved, the integrated circuit devices become smaller. Accordingly, the density of power consumption of electronic components within the integrated circuit devices has increased, which, in turn, increases the average junction temperature of the integrated circuit device. If the temperature of the integrated circuit device becomes too high, the integrated circuits may be damaged or destroyed. This issue becomes even more critical when multiple integrated circuit devices are incorporated in a stacked configuration. As will be understood to those skilled in the art, when multiple integrated circuit devices are stacked, some of the integrated circuit devices will be “internally” positioned between an adjacent integrated circuit device and a substrate to which the stacked integrated circuit devices are attached or will be positioned between a pair of adjacent integrated circuit devices. As such, these internally positioned integrated circuit devices are partially isolated from thermal management solutions, such as heat spreaders, since the integrated circuit devices and/or the substrate to which the integrated circuit devices may be adjacent, are generally not efficient thermal conductors. Thus, the internally positioned integrated circuit devices may exceed their temperature limits and be damaged or destroyed, leading to the failure of the entire integrated circuit package. Alternatively, if the integrated circuits have thermal throttling control, they may reduce their operating frequency and, thus, their power to operate at lower temperature and avoid failures. However, this results in lower overall performance.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of an integrated circuit structure having stacked integrated circuit devices coupled to a direct fluid contact heat dissipation device, wherein the underfill material of each of the stacked integrated circuits devices may include channels to facilitate heat removal from at least one of the stacked integrated circuit devices, according to an embodiment of the present description.

FIGS. 2-5 are top plan views of various channel configurations along line 2-2 of FIG. 1, according to embodiments of the present description.

FIG. 6 is a side cross-sectional view of an integrated circuit structure having at least one first fluid channel and at least one second fluid channel, wherein at least one fluid conduit extends between the at least one first fluid channel and the at least one second fluid channel, according to another embodiment of the present description.

FIGS. 7-12 are cross-sectional views of a method of fabricating the integrated circuit structure of FIG. 6, according to one embodiment of the present description.

FIG. 13 is a flow diagram of a method of fabricating an integrated circuit structure, according to one embodiment of the present description.

FIG. 14 is an electronic device/system, according to an embodiment of the present description.

### DESCRIPTION OF EMBODIMENTS

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present invention. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures. as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description may include an integrated circuit structure having a substrate, a first integrated circuit device electrically attached to the substrate, a second integrated circuit device electrically attached to the first integrated circuit device, at least one first level channel between the substrate and the first integrated circuit device and/or at least one second level channel between the first integrated circuit device and the second integrated circuit device, and a heat dissipation device attached to the substrate which defines a fluid chamber, wherein the at least one first level channel and/or the at least one second level channel is opened to the fluid chamber, such that when a heat transfer fluid is introduced into the fluid chamber, the heat transfer fluid may make direct contact with the first integrated circuit device and/or the second integrated circuit device within the at least one first level channel and/or the at least one second level channel. In further embodiments, at least one conduit may extend between the at least one first level channel and the at least one second level channel.

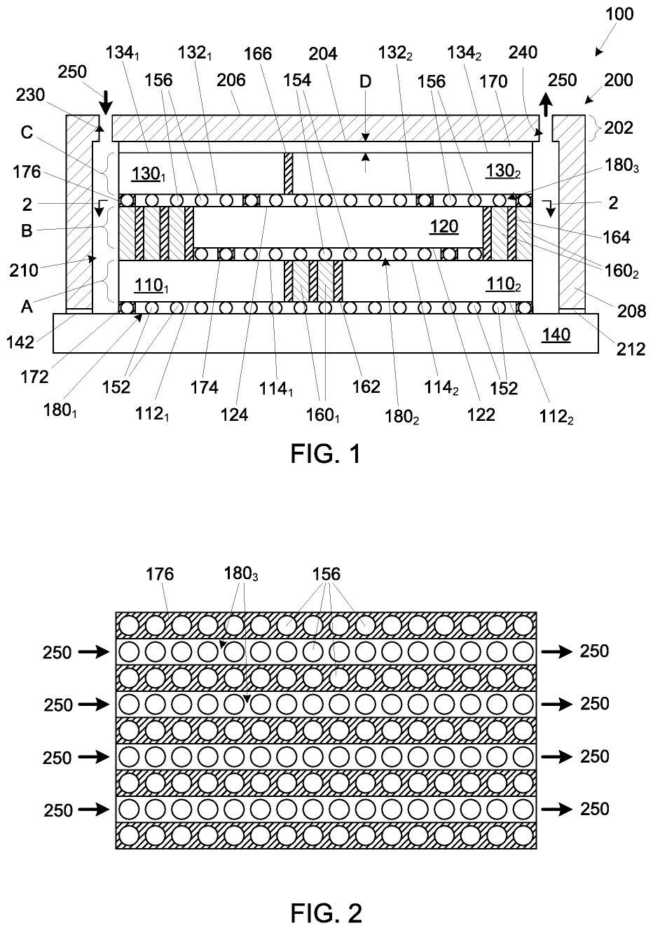

FIG. 1 illustrates an integrated circuit package having stacked integrated circuit devices coupled with a heat dissipation structure according to an embodiment of the present description. In the production of integrated circuit packages, integrated circuit devices are generally mounted on substrates, which provide electrical communication routes between the integrated circuit devices and/or with external components. As shown in FIG. 1, an integrated circuit assembly or package 100 may comprise a plurality of integrated circuit devices (illustrated as two first level A integrated circuit devices 110₁ and 110₂, one second level B integrated circuit device 120, and two third level C integrated circuit devices 130₁ and 130₁) attached to a substrate 140. The integrated circuit devices may be any appropriate devices, including, but not limited to microprocessors, chipsets, graphics devices, wireless devices, memory devices, application specific integrated circuits, combinations thereof, stacks thereof, or the like. The substrate 140 may be any appropriate structure, including, but not limited to, an interposer, a printed circuit board, a motherboard, and the like.

The substrate 140 may be primarily composed of an appropriate dielectric material, including, but not limited to, bismaleimide triazine resin, fire retardant grade 4 material, polyimide materials, glass reinforced epoxy matrix material, and the like, as well as laminates or multiple layers thereof. The substrate conductive routes (not shown), also known as metallization, may be composed of any conductive material, including but not limited to metals, such as copper and aluminum, and alloys thereof. As will be understood to those skilled in the art, the substrate conductive routes (not shown) may be formed as a plurality of conductive traces (not shown) formed on layers of dielectric material (constituting the dielectric material of the substrate 140), which are connected by conductive vias (not shown). Furthermore, the substrate 140 may be either a cored or a coreless substrate.

In one embodiment, the two first level integrated circuit devices 110₁ and 110₂ may be attached to the first surface 142 (also known as the “die side”) of the substrate 140 through the plurality of device-to-substrate interconnects 152, such as reflowable solder bumps or balls, in a configuration generally known as a flip-chip or controlled collapse chip connection (“C4”) configuration. The device-to-substrate interconnects 152 may extend from bond pads (not shown) on first surfaces 112₁ and 112₂ of the first level integrated circuit devices 110₁ and 110₂, respectively, and bond pads (not shown) on the first surface 142 of the substrate 140. The integrated circuit device bond pads (not shown) of the first level integrated circuit devices 110₁ and 110₂ may be in electrical communication with circuitry (not shown) within the first level integrated circuit devices 110₁ and 110₂. The substrate 140 may include at least one conductive route (not shown) extending therethrough or thereon to form electrical connections between first level integrated circuit devices 110₁ and 110₂ and/or from the first level integrated circuit devices 110₁ and 110₂ to external components (not shown).

The second level integrated circuit device 120 may be attached to second surfaces 114₁ and 114₂ of the first level integrated circuit devices 110₁ and 110₂, respectively, through a plurality of device-to-device interconnects 154, such as reflowable solder bumps or balls in a C4 configuration. The device-to-device interconnects 154 may extend from bond pads (not shown) on a first surface 122 of the second level integrated circuit device 120 and bond pads (not shown) on the second surfaces 114₁ and 114₂ of the first level integrated circuit devices 110₁ and 110₂, respectively. The bond pads (not shown) on the second surfaces 114₁ and 114₂ of the first level integrated circuit devices 110₁ and 110₂, respectively, may be in electrical communication with integrated circuitry (not shown) and/or through-silicon vias (not shown) within the first level integrated circuit devices 110₁ and 110₂. The bond pads (not shown) on the first surface 122 of the second level integrated circuit device 120 may be in electrical communication with integrated circuitry (not shown) within the second level integrated circuit device 120.

As further shown in FIG. 1, a plurality of first level conductive pillars 160₁ may extend through a layer of first level dielectric material 162 positioned between the two first level integrated circuit device 110₁ and 110₂. Respective device-to-device interconnects 154 may connect the second level integrated circuit device 120 to the plurality of first level conductive pillars 160₁ and respective device-to-substrate interconnects 152 may connect the plurality of first level conductive pillars 160₁ to the substrate 140. The first level conductive pillars 160₁ may be formed from a conductive material and, thus, the second level integrated circuit device 120 may be directly connected with the substrate 140. The first level conductive pillars 160₁ may be formed from any appropriate material, including, but not limited to, metals, such as copper and silver. The first level conductive pillars 160₁ and the layer of first level dielectric material 162 may comprise organic substrates with metal interconnects (e.g. plated through hole vias or microvias), silicon substrates with metal interconnects (e.g. through silicon vias), and glasses with metal interconnects (e.g. through glass vias).

The third level integrated circuit devices 130₁ and 130₂ may be attached to a second surface 124 of the second level integrated circuit device 120 through a plurality of device-to-device interconnects 156. The device-to-device interconnects 156 may extend from bond pads (not shown) on first surfaces 132₁ and 132₂ of the third level integrated circuit devices 130₁ and 130₂, respectively, and bond pads (not shown) on the second surface 124 of the second level integrated circuit device 120. The bond pads (not shown) on the second surface 124 of the second level integrated circuit device 120 may be in electrical communication with integrated circuitry (not shown) and/or through-silicon vias (not shown) within the second level integrated circuit device 120. The bond pads (not shown) on the first surfaces 132₁ and 132₂ of the third level integrated circuit devices 130₁ and 130₂, respectively, may be in electrical communication with integrated circuitry (not shown) within the third level integrated circuit devices 130₁ and 130₂, respectively.

As further shown in FIG. 1, a plurality of second level conductive pillars 160₂ may extend through a layer of second level dielectric material 164 positioned adjacent the second level integrated circuit device 120 (shown on opposing sides thereof). Respective device-to-device interconnects 156 may connect the third level integrated circuit devices 130₁ and 130₂ to the plurality of second level conductive pillars 160₂ and the plurality of second level conductive pillars 160₂ may be directly attached to the respective first level integrated circuit devices 110₁ and 110₂. Thus, the third level integrated circuit devices 130₁ and 130₂ may be directly connected with respective first level integrated circuit devices 110₁ and 110₂. Any gaps between the third level integrated circuit devices 130₁ and 130₂ may be filled with a dielectric material 166. The second level conductive pillars 160₂ may be formed from any appropriate material, including, but not limited to, metals, such as copper and silver. The second level conductive pillars 160₂ and the layer of second level dielectric material 164 may comprise organic substrates with metal interconnects (e.g. plated through hole vias or microvias), silicon substrates with metal interconnects (e.g. through silicon vias), and glasses with metal interconnects (e.g. through glass vias).

The device-to-substrate interconnects 152, the device-to-device interconnects 154, and the device-to-device interconnects 156 are not limited to solder bumps or balls, as illustrated, but may also be formed through direct copper-to-copper contacts or through conductive adhesive. However, when solder materials are used, they may be any appropriate material, including, but not limited to, tin, lead/tin alloys, such as 63% tin/37% lead solder, and high tin content alloys (e.g. 90% or more tin), such as tin/bismuth, eutectic tin/silver, ternary tin/silver/copper, eutectic tin/copper, and similar alloys. The solder may be reflowed, either by heat, pressure, and/or sonic energy to secure to form the device-to-substrate interconnects 152, the device-to-device interconnects 154, and/or the device-to-device interconnects 156.

As further illustrated in FIG. 1 and according to one embodiment of the present description, a heat dissipation device 200, such as a heat spreader, may be attached to the first surface 142 of the substrate 140, wherein the heat dissipation device 200 defines a fluid chamber 210. In one embodiment of the present description, the heat dissipation device 200 may comprise a main body 202, having a first surface 204 and an opposing second surface 206, and a boundary wall 208 extending from the first surface 204 of the main body 202 of the heat dissipation device 200. The boundary wall 208 may be attached or sealed to the first surface 142 of the substrate 140 with an attachment adhesive or sealant layer 212.

As shown in FIG. 1, the fluid chamber 210 may be substantially defined by the first surface 204 of the main body 202 of the heat dissipation device 200, the boundary wall 208 of the heat dissipation device 200, the substrate 120, and the components on the substrate 120 surrounded by the boundary wall 208 (e.g. integrated circuit devices 110₁, 110₂, 120, 130₁, and 130₂, etc.). An inlet port 230 may extend from the second surface 206 of the main body 202 of the heat dissipation device 200 to the first surface 204 of the main body 202 of the heat dissipation device 200. An outlet port 240 may extend from the first surface 204 of the main body 202 of the heat dissipation device 200 to the second surface 206 of the main body 202 of the heat dissipation device 200. A heat transfer fluid 250 (illustrated generically as a down arrow (left side) and an up arrow (right side)) may flow into the fluid chamber 210 through the inlet port 230 and out of the fluid chamber 210 through the outlet port 240. In one embodiment, the fluid chamber 210 is sealed to contain the heat transfer fluid 250. The heat transfer fluid 250 may be any appropriate gas or liquid, or a combination thereof. In one embodiment, the heat transfer fluid 250 may comprise water. In another embodiment, the heat transfer fluid 250 may comprise a dielectric refrigerant. In a further embodiment, the heat transfer fluid 250 may comprise an oil. In other embodiments, the heat transfer fluid 250 may be comprised of two phases (such as liquid water and water vapor, or liquid-phase and gas-phase dielectric refrigerant) that exist simultaneously in one or more regions of the fluid chamber 210.

It is understood that the heat transfer fluid 250 may not be compatible with all of the components within the electronic assembly, such as the substrate 140. For example, the components may be made of porous material that may lead to the heat transfer fluid 250 migrating though the porous material and damaging components within the electronic assembly. Thus, a coating (not shown) may be deposited on exposed surfaces of such components.

The first surface 204 of the main body 202 of the heat dissipation device 200 may be thermally coupled with a second surface 134₁ and 134₂ of the third level integrated circuit devices 130₁ and 130₂, respectively. In one embodiment, the heat dissipation device 200 may be thermally coupled to the second surface 134₁ and 134₂ of the third level integrated circuit devices 130₁ and 130₂, respectively, with a thermal interface material 170, such as a grease or polymer, or epoxy filled with high thermal conductivity fillers such as metal particles or silicon particles, to facilitate heat transfer therebetween. The heat dissipation device 200 may be made of any appropriate thermally conductive material, including, but not limited to at least one metal material and alloys of more than one metal, or highly doped glass or highly conductive ceramic material, such as aluminum nitride. In one embodiment, the heat dissipation device 200 may comprise copper, nickel, aluminum, alloys thereof, laminated metals including coated materials (such as nickel coated copper), and the like.

As illustrated in FIG. 1, the heat dissipation device 200 may be a single material throughout, such as when the heat dissipation device 200 including the heat dissipation device footing 208 is formed by a single process step, including but not limited to stamping, skiving, molding, and the like. However, embodiment of the present description may also include heat dissipation device 200 made of more than one component. For example, the heat dissipation device foot 208 may be formed separately from the main body 202, then attached together to form the heat dissipation device 200. In various embodiments, the heat dissipation device footing 208 may be a plurality of walls, pillars, or the like, or may be a single “picture frame” structure surrounding the integrated circuit device 110₁, 110₂, 120, 130₁, and 130₂.

The attachment adhesive or sealant layer 212 may be any appropriate material, including, but not limited to, silicones (such as polydimethylsiloxane), epoxies, and the like. It is understood that the heat dissipation device footing 208 not only secures the heat dissipation device 200 to the substrate 140, but also maintains a desired distance D between the first surface 204 of the heat dissipation device 200 and second surfaces 134₁, 134₂ of the third level integrated circuit devices 130₁, 130₂, respectively. This distance D may be referred to as the “bond line thickness”.

In a further embodiment, the underfill material within the microelectronic package 100 may be utilized to form channels under at least one of the integrated circuit devices 110₁, 110₂, 120, 130₁ and 130₂, such that the heat transfer fluid 250 can flow through the channels to remove heat from the integrated circuit devices 110₁, 110₂, 120, 130₁ and 130₂.

In an embodiment, at least one first channel 180₁ may be formed by patterning a first underfill material 172 between the first surfaces 112₁ and 112₂ of the first level integrated circuit devices 110₁ and 110₂, respectively, and the first surface 142 of the substrate 140. In one embodiment, the heat transfer fluid 250 may directly contact the first surfaces 112₁ and 112₂ of the first level integrated circuit devices 110₁ and 110₂ to remove heat therefrom. In a further embodiment, the first underfill material 172 may surround at least one device-to-substrate interconnects 152. In one embodiment, at least one of the device-to-substrate interconnects 152 extends through the at least one first channel 180₁.

In an embodiment, a second underfill material 174 may be patterned between the first level A of integrated circuit devices and the second level B of integrated circuit devices (i.e. second level integrated circuit device 120, and, may include the plurality of second level conductive pillars 160₂ and the second level dielectric material 164) to define at least one second channel 180₂. In one embodiment, the first surfaces 122 of the second level integrated circuit device 120 may be exposed in the at least one second channel 180₂, such that the heat transfer fluid 250 may directly remove heat therefrom. In another embodiment, the second surfaces 114₁ and 114₂ of the first level integrated circuit devices 110₁ and 110₂ may be exposed in the at least one second channel 180₂, such that the heat transfer fluid 250 may directly remove heat therefrom. In a further embodiment, the second underfill material 174 may surround at least one device-to-device interconnects 154. In one embodiment, at least one of the device-to-device interconnects 154 extends through the at least one second channel 180₂.

In another embodiment, a third underfill material 176 may be patterned between the second level B of integrated circuit devices and a third level C of integrated circuit devices (i.e. third level integrated circuit devices 130₁, 130₂) to define at least one third channel 180₃. In one embodiment, the first surfaces 132₁ and 132₂ of the third level integrated circuit devices 130₁ and 130₂ may be exposed in the at least one third channel 180₃, such that the heat transfer fluid 250 may directly contact to remove heat therefrom. In another embodiment, the second surface 124 of the second level integrated circuit devices 120 may be exposed in the at least one third channel 180₃, such that the heat transfer fluid 250 may directly contact to remove heat therefrom. In a further embodiment, the third underfill material 176 may surround at least one device-to-device interconnects 156. In one embodiment, at least one of the device-to-device interconnects 156 extends through the at least one third channel 180₃.

The first underfill material 172, the second underfill material 174, and the third underfill material 176 may be any appropriate material, including, but not limit to, epoxy materials. In one embodiment, the first underfill material 172, the second underfill material 174, and/or the third underfill material 176 may be a photo-definable dielectric, such as polymers with photoactive materials and inorganic fillers, with adhesion promoters, such as silanes, organotitanates, or zircoaluminates, disposed therein. In another embodiment, the first underfill material 172, the second underfill material 174, and/or the third underfill material 176 may be formed by adding photo-sensitive additives, such as benzoin derivative, triphenyl sulfonium nonaflate, to a non-conductive film (NCF). In a further embodiment, the first underfill material 172, the second underfill material 174, and/or the third underfill material 176 may be formed by stenciling, screen printing, and/or lithography.

FIG. 2 illustrates an embodiment of the configuration of channels 180₁, 180₂, and 180₃, wherein FIG. 2 specifically shows third channel 180₃ along line 2-2 of FIG. 1. As shown, the device-to-device interconnects 156 may be aligned in rows, wherein alternating rows of device-to-device interconnects 156 are encapsulated in the third underfill material 176 to form channels 180₃. The embodiment of FIG. 2 results in a portion of the device-to-device interconnects 156 extending through the underfill material 176 and a portion of the device-to-device interconnects 156 extending thorough the third channels 180₃. In one embodiment, the plurality of third channels 180₃ may be substantially parallel to the flow of the heat transfer fluid (illustrated by arrows 250), e.g. in the general direction of the inlet port 230 to the outlet port 240 (shown in FIG. 1).

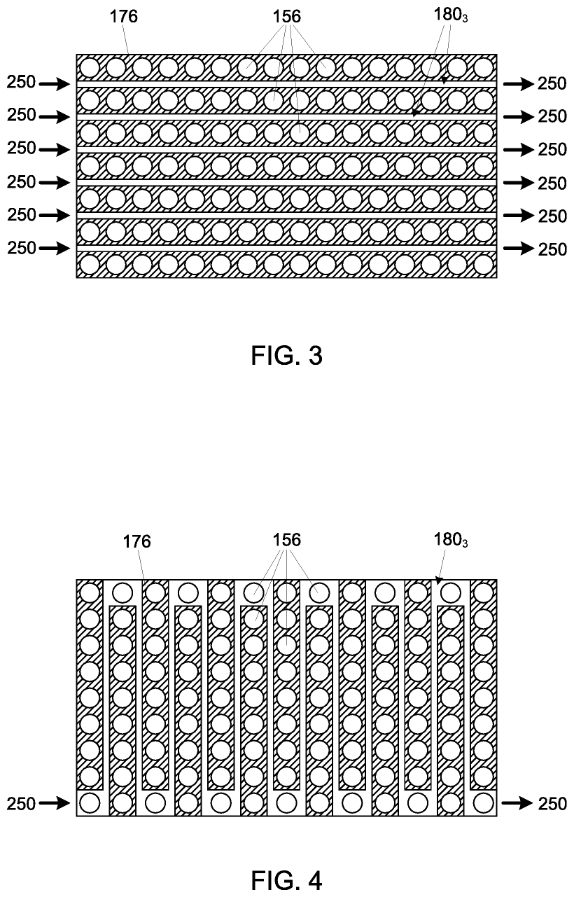

FIG. 3 illustrates another embodiment of the configuration of the channels 180₁, 180₂, and 180₃. As shown, the device-to-device interconnects 156 may be aligned in rows, wherein all of the device-to-device interconnects 156 are encapsulated in the third underfill material 176 and the third underfill material 176 is patterned to form a plurality of third channels 180₃ between the device-to-device interconnects 156. In one embodiment, the plurality of third channels 180₃ may be substantially parallel to the flow of the heat transfer fluid (illustrated by arrows 250), e.g. in the general direction of the inlet port 230 to the outlet port 240 (shown in FIG. 1).

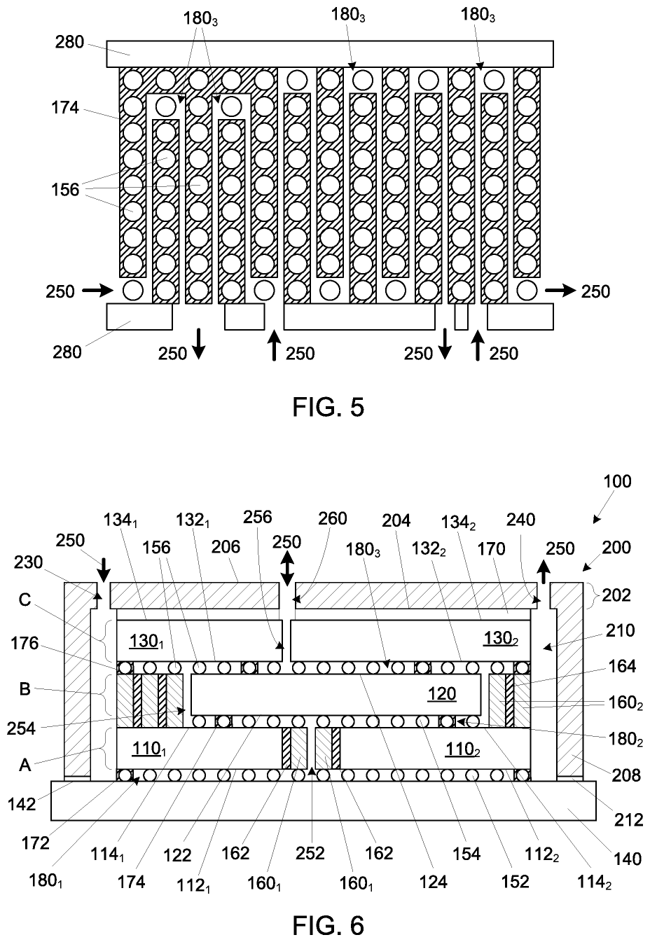

It is understood that the channels 180₁, 180₂, and 180₃ can have any appropriate configuration. For example, FIG. 4 illustrates an embodiment of the configuration of a single third channel 180₃ that is patterned to travel a serpentine route through the device-to-device interconnects 156. In a further example, FIG. 5 illustrates an embodiment of a combination of third channels 180₃ having various serpentine routes and may include barrier walls 280, which allows for various entrance and exit points for the heat transfer fluid 250. Although the illustrated channels 180₃ are one row/column of interconnections 156, they can also be formed from multiple rows/columns of interconnects.

FIG. 6 illustrates an integrated circuit package having stacked integrated circuit devices coupled with a heat dissipation structure according to another embodiment of the present description. The embodiment of FIG. 6 contains the components of FIG. 1, but includes embodiments relating to the use of conduits to connect channels between differing levels (e.g. the first level A, the second level B, and the third level C). In one embodiment, a first level conduit 252 may be formed to connect the at least one first channel 180₁ to the at least one second channel 180₂. The first level conduit 252 may be formed in the first level dielectric material 162. In another embodiment, a second level conduit 254 may be formed to connect the at least one second channel 180₂ to the at least one third channel 180₃. The second level conduit 254 may be formed in the second level dielectric material 164. In further embodiment, a third level conduit 256 may be formed to connect the at least one third channel 180₃ to an additional inlet/outlet port 260 extending through the main body 202 of the heat transfer device 200. The third level conduit 256 may be formed utilizing the gap between the third level integrated circuit devices 130₁ and 130₂.

Although the embodiments shown in FIGS. 1-6 related to two stacked integrated circuit devices, the embodiments are not so limited, as there may be more than on sets of stacked integrated circuit devices and/or more than two stacked integrated circuit devices.

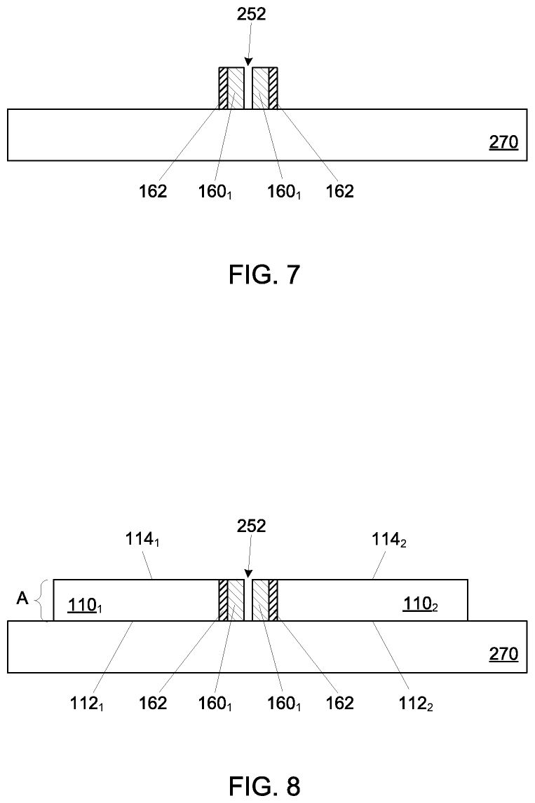

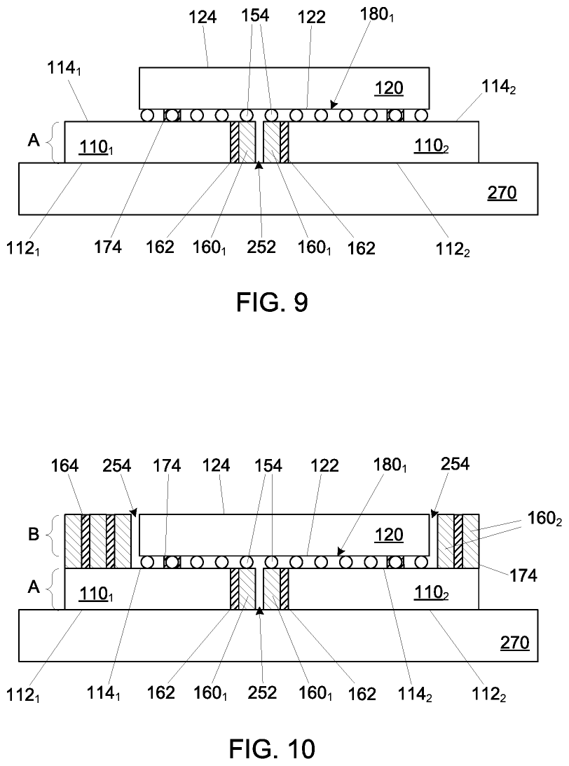

Although it is understood that the embodiments shown in FIGS. 1-6 may be fabricated in any appropriate manner, FIGS. 7-12 illustrate an exemplary method of fabrication for the embodiment of FIG. 6. As shown in FIG. 7, a carrier 270 may be provided wherein the plurality of first level conductive pillars 160₁ are formed thereon by any known processes. The photo-definable first level dielectric material 162 may be laminated over the carrier 270, exposed, and developed to pattern the first level dielectric material 162 adjacent the first level conductive pillars 160₁. As shown, the first level conduit 252 may also be formed. It is understood that the first level conductive pillars 160₁ and first level dielectric material 162 may be pre-formed and place on the carrier 270. As shown in FIG. 8, the first surfaces 112₁ and 112₂ of each of a plurality of first level integrated circuit devices 110₁ and 110₂, respectively, may be attached adjacent the first level conductive pillars 160₁ and first level dielectric material 162, such as by an adhesive, to the carrier 270. As shown in FIG. 9, the plurality of device-to-device interconnects 154 may be attached to the second surfaces 114₁ and 114₂ of the first level integrated circuit devices 110₁ and 110₂, respectively, and the second underfill material 164 patterned thereon to form the at least one first channel 180₁, as previously discussed. The second level integrated circuit device 120 may be attached to respective first level integrated circuit devices 110₁ with the plurality of device-to-device interconnects 154.

As shown in FIG. 10, second level conductive pillars 160₂ and second level dielectric material 164 may be formed on the second surfaces 114₁ and 114₂ of the first level integrated circuit devices 110₁ and 110₂, respectively, and adjacent the second level integrated circuit device 120. The patterning of the second level dielectric material 154 may form the second level conduits 254.

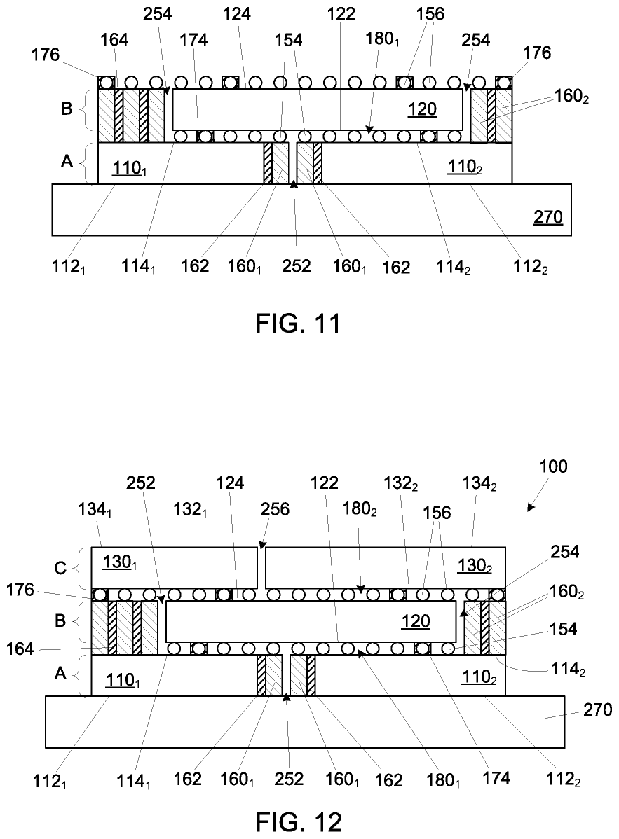

As shown in FIG. 11, the plurality of device-to-device interconnects 156 may be attached to the second surface 124 of the second level integrated circuit device 120. The plurality of device-to-device interconnects 156 may also be attached to the second level conductive pillars 160₂. Further, the third underfill material 176 may be patterned the second surface 124 of the second level integrated circuit device 120 and/or the conductive pillars 160₂.

As shown in FIG. 12, the third level integrated circuit devices 130₁ and 130₂, may be attached to the second level integrated circuit device 120 and the second level conductive pillars 160₂ with the plurality of device-to-device interconnects 156. Any gap between the third level integrated circuit devices 130₁ and 130₂ may be used to form the third level conduits 256. The heat dissipation device 200 (not shown) may be attached to form the integrated circuit structure of FIG. 6.

Although the method illustrated in FIGS. 7-12 is for an integrated circuit device to integrated circuit device process, the method can be used for an integrated circuit wafer to an integrated circuit wafer process, or an integrated circuit device to an integrated circuit wafer process, as will be understood to those skilled in the art.

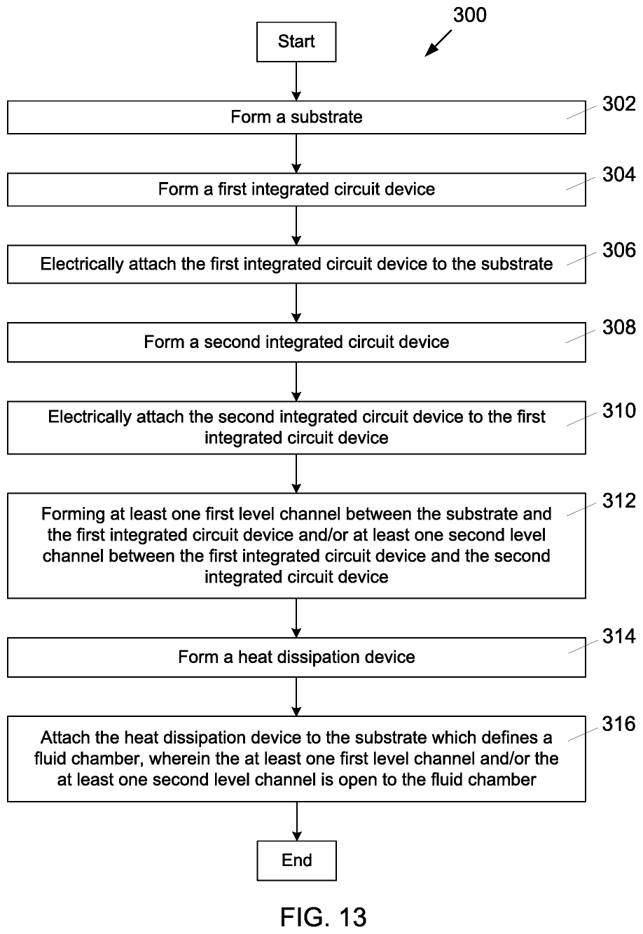

FIG. 13 is a flow chart of a process 300 of fabricating an integrated circuit structure according to an embodiment of the present description. As set forth in block 302, a substrate may be formed. A first integrated circuit device may be formed, as set forth in block 304. As set forth in block 306, the first integrated circuit device may be electrically attached to the substrate. A second integrated circuit device may be formed, as set forth in block 308. As set forth in block 310, the second integrated circuit device may be electrically attached to the first integrated circuit device. At least one first level channel may be formed between the substrate and the first integrated circuit device and/or between the first integrated circuit device and the second integrated circuit device, as set forth in block 312. As set forth in block 314, a heat dissipation device may be formed. The heat dissipation device may be attached to the substrate which defines a fluid chamber, wherein the at least one first level channel and/or the at least one second level channel is opened to the fluid chamber, as set forth in block 316.

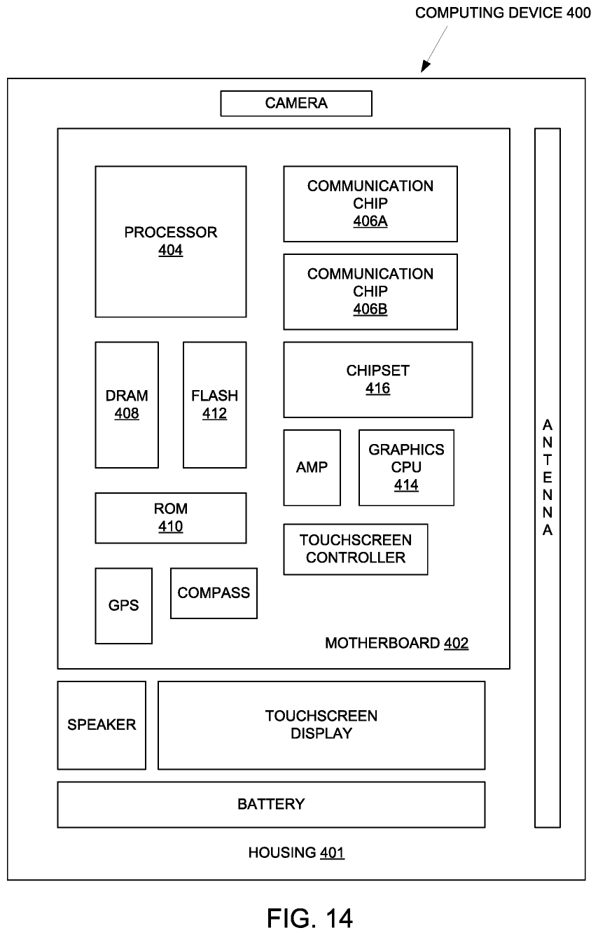

FIG. 14 illustrates an electronic or computing device 400 in accordance with one implementation of the present description. The computing device 400 may include a housing 401 having a board 402 disposed therein. The board 402 may include a number of integrated circuit components, including but not limited to a processor 404, at least one communication chip 406A, 406B, volatile memory 408 (e.g., DRAM), non-volatile memory 410 (e.g., ROM), flash memory 412, a graphics processor or CPU 414, a digital signal processor (not shown), a crypto processor (not shown), a chipset 416, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 402. In some implementations, at least one of the integrated circuit components may be a part of the processor 404.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

At least one of the integrated circuit components may include an integrated circuit structure comprising a substrate, a first integrated circuit device electrically attached to the substrate, a second integrated circuit device electrically attached to the first integrated circuit device, at least one first level channel between the substrate and the first integrated circuit device and/or at least one second level channel between the first integrated circuit device and the second integrated circuit device, and a heat dissipation device attached to the substrate which defines a fluid chamber, wherein the at least one of the first level channel and/or the at least one second level channel is opened to the fluid chamber.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-14. The subject matter may be applied to other integrated circuit devices and assembly applications, as well as any appropriate electronic application, as will be understood to those skilled in the art.

Having thus described in detail embodiments of the present invention, it is understood that the invention defined by the appended claims is not to be limited by particular details set forth in the above description, as many apparent variations thereof are possible without departing from the spirit or scope thereof

What is claimed is:

1. An integrated circuit assembly, comprising:
a substrate;
a first integrated circuit device electrically attached to the substrate;
a second integrated circuit device electrically attached to the first integrated circuit device;
at least one first level channel between the substrate and the first integrated circuit device and/or at least one second level channel between the first integrated circuit device and the second integrated circuit device; and
a heat dissipation device attached to the substrate which defines a fluid chamber, wherein the at least one first level channel and/or the at least one second level channel is open to the fluid chamber.

2. The integrated circuit assembly of claim 1, wherein the at least one first level channel is formed in a first underfill material disposed between the substrate and the first integrated circuit device.

3. The integrated circuit assembly of claim 2, wherein the first underfill material surrounds at least one interconnect, wherein the at least one interconnect electrically connects the first integrated circuit device and the substrate.

4. The integrated circuit assembly of claim 3, wherein the at least one first level channel is formed between adjacent interconnects.

5. The integrated circuit assembly of claim 1, wherein the at least one second level channel is formed in a second underfill material disposed between the first integrated circuit device and the second integrated circuit device.

6. The integrated circuit assembly of claim 5, wherein the second underfill material surrounds at least one interconnect and wherein the at least one interconnect electrically connects the first integrated circuit device and the second integrated circuit device.

7. The integrated circuit assembly of claim 6, wherein the at least one second level channel is formed between adjacent interconnects.

8. The integrated circuit assembly of claim 1, further comprising at least one conduit connecting the first level channel and the second level channel.

9. The integrated circuit assembly of claim 1, at least one conductive pillar electrically coupling the second integrated circuit and the substrate.

10. The integrated circuit assembly of claim 1, further comprising a third integrated circuit device electrically attached to the second integrated circuit device with at least one third level channel between the second integrated circuit device and the third integrated circuit device.

11. The integrated circuit assembly of claim 10, wherein the at least one third level channel is formed in a third underfill material disposed between the second integrated circuit device and the third integrated circuit device.

12. The integrated circuit assembly of claim 11, wherein the third underfill material surrounds at least one interconnect, wherein the at least one interconnect electrically connects the second integrated circuit device and the third integrated circuit device.

13. The integrated circuit assembly of claim 12, wherein the at least one third level channel is formed between adjacent interconnects.

14. The integrated circuit assembly of claim 10, further comprising at least one conduit connecting the second level channel and the third level channel.

15. The integrated circuit assembly of claim 10, at least one conductive pillar electrically coupling the third integrated circuit and the first integrated circuit.

16. The integrated circuit assembly of claim 1, wherein the heat dissipation device includes an input port extending from a second surface of a main body of the heat dissipation device to the first surface of the main body of the heat dissipation device, and an output port extending from the first surface of the main body of the heat dissipation device to the second surface of the main body of the heat dissipation device.

17. The integrated circuit assembly of claim 1, further comprising a heat transfer fluid disposed in the fluid chamber of the heat dissipation device.

18. An electronic system, comprising:
a housing;
a substrate in the housing;
a first integrated circuit device electrically attached to the substrate;
a second integrated circuit device electrically attached to the first integrated circuit device;
at least one first level channel between the substrate and the first integrated circuit device and/or at least one second level channel between the first integrated circuit device and the second integrated circuit device; and
a heat dissipation device attached to the substrate which defines a fluid chamber, wherein the at least one first level channel and/or the at least one second level channel is open to the fluid chamber.

19. The electronic system of claim 18, wherein the at least one first level channel is formed in a first underfill material disposed between the substrate and the first integrated circuit device.

20. The electronic system of claim 18, wherein the at least one second level channel is formed in a second underfill material disposed between the first integrated circuit device and the second integrated circuit device.

21. The electronic system of claim 18, further comprising at least one conduit connecting the first level channel and the second level channel.

22. The electronic system of claim 18, at least one conductive pillar electrically coupling the second integrated circuit and the substrate.

23. The electronic system of claim 18, further comprising a third integrated circuit device electrically attached to the second integrated circuit device with at least one third level channel between the second integrated circuit device and the third integrated circuit device, wherein the third level channel is open to the fluid chamber of the heat dissipation device.

24. The electronic system of claim 23, further comprising at least one conduit connecting the second level channel and the third level channel.

25. The electronic system of claim 23, at least one conductive pillar electrically coupling the third integrated circuit and the first integrated circuit.
